(19) United States
(12) Patent Application Publication
(10) Pub. No.: US 2026/0198296 A1
(43) Pub. Date: Jul. 9, 2026

(54) METAL RIVET STRUCTURE AND METHOD FOR FABRICATING THE SAME

(71) Applicant: Taiwan Semiconductor Manufacturing Company, Ltd., Hsinchu (TW)

(72) Inventors: Kuen-Ming Liou, Tainan (TW); Chih-Hao Chen, Hsinchu (TW); Wen-Yen Chen, Hsinchu (TW)

(21) Appl. No.: 19/011,432

(22) Filed: Jan. 6, 2025

(51) Int. Cl. H01L 23/528; H01L 21/3213; H01L 21/768; H01L 23/532

(52) U.S. Cl. CPC H10W 20/435; H10P 50/667; H10W 20/035; H10W 20/056; H10W 20/081; H10W 20/425; H10W 20/4441

(57) ABSTRACT

A semiconductor structure comprises: a substrate; a dielectric layer above the substrate; a second dielectric layer disposed on the dielectric layer; a metal plug disposed in the dielectric layer and comprising a nonplanar top surface of the metal plug, the nonplanar top surface of the metal plug defining a recess; and a metal rivet structure. The metal rivet structure comprises: a shaft portion penetrating the second dielectric layer and comprising a bottom surface of the shaft portion; and a head portion located in the dielectric layer and comprising a top surface of the head portion and a nonplanar bottom surface of the head portion, wherein the top surface of the head portion is coplanar with the bottom surface of the shaft portion, and the nonplanar bottom surface of the head portion mates with the nonplanar top surface of the metal plug.

### FIELD

Embodiments of the present disclosure relate generally to metal wires in semiconductor chips, and more particularly to meal rivet structure and method for fabricating the same.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional diagram illustrating an example semiconductor structure in accordance with some embodiments.

FIG. 1B is a diagram illustrating a close-up view of a portion of the semiconductor structure of FIG. 1A in accordance with some embodiments.

FIG. 2 is a flowchart diagram illustrating an example method in accordance with some embodiments.

FIGS. 3A-3D are cross-sectional diagrams illustrating the cross-sections of the structures in various fabrication stages in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

The resistivity of metal wires in the back-end-of-line (BEOL) of semiconductor chips is a critical factor influencing their performance and power consumption. Historically, aluminum was the primary metal used for interconnects, but due to its limitations, copper (Cu) has become the dominant material. Copper, as the material used for metal wires, has the following advantages: low resistivity (~1.72 μΩ-cm), high conductivity, and good electromigration resistance.

Various factors affect resistivity in BEOL metal wires. The intrinsic resistivity of the metal itself is a fundamental factor. Copper, with its lower resistivity, is preferred over aluminum. Resistivity increases with temperature, affecting the overall performance of the chip. Imperfections and impurities introduced during the manufacturing process can increase resistivity. Mechanical stress can alter the crystal structure of the metal, affecting its resistivity.

In addition, geometry plays a critical role in affecting resistivity in BEOL metal wires. The dimensions of the metal wires, including width and thickness, influence resistance. As feature sizes (e.g., critical dimensions, or “CDs”) shrink, the relative impact of surface and grain boundary scattering increases, leading to higher resistivity. Surface scattering and grain boundary scattering are two primary mechanisms that contribute to the scattering of charge carriers (electrons and holes) in semiconductor materials. These scattering events can significantly influence the electrical conductivity and other properties of semiconductors.

Surface scattering occurs when charge carriers interact with the surface of a semiconductor material. The surface atoms have different electronic properties than the bulk atoms, creating a potential barrier that can scatter carriers. A variety of factors, such as surface roughness, surface defects, surface treatments (e.g., oxidation, passivation), and the like, affect the surface scattering.

In polycrystalline metals, grain boundaries are the interfaces between different crystallites. These boundaries disrupt the periodic lattice structure and can act as scattering centers for charge carriers. Grain size distribution, grain boundary orientation, and grain boundary defects all determine the grain boundary scattering.

Tungsten (W) is a crucial material used in vias within semiconductor chips due to its unique properties. Tungsten exhibits low electrical resistivity, ensuring efficient conduction of electrical signals through the vias. Tungsten can conformally fill vias with high aspect ratios, ensuring reliable electrical connections even in deep, narrow structures. Tungsten's high melting point allows it to withstand the high temperatures involved in semiconductor manufacturing processes. Tungsten is resistant to electromigration, a phenomenon that can lead to the degradation and failure of metal interconnects. Moreover, tungsten films have low intrinsic stress, reducing the risk of mechanical stress-induced failures in the chip. Additionally, tungsten has good adhesion to silicon and other materials used in semiconductor manufacturing.

Tungsten offers lower resistivity and better electromigration resistance compared to aluminum, making it a more suitable choice for advanced semiconductor technologies. While copper is widely used for interconnects due to its low resistivity, tungsten can be a viable alternative in certain applications, especially for vias with high aspect ratios or where copper diffusion is a concern.

As a result, tungsten is widely used in various applications in semiconductor chips. One of those applications is vertical interconnects. Tungsten is used to fill vias that connect different layers of the chip, enabling vertical signal transmission. Another application is contact plugs. Tungsten plugs are used to connect the active devices (e.g., transistors) to the metal interconnects, ensuring reliable electrical contact.

In one example, tungsten is used as the material for metal plugs in the first contact layer (sometimes referred to as the “VD layer”) that is between the first metal layer (sometimes referred to as the “M0 layer”) and the device connection layer (sometimes referred to as the “metal-over-diffusion layer” or the “MD layer”). As explained above, as the critical dimensions shrink in advanced technology nodes (e.g., 2-nanometer node, or “N2”), the resistance of metal plugs in the VD layer increases due to the impact of surface and grain boundary scattering. It should be noted that although the VD layer is used as an example, the techniques disclosed herein are also applicable to other layers such as “VG.”

One way to address this issue is to utilize alternative metal materials with lower resistivity, longer electron mean free path (i.e., the average distance an electron travels between collisions with other particles), and acceptable cost. However, integrating new materials with existing or conventional process flows is generally challenging. For example, some (not all) new materials might react with existing process chemicals, leading to contamination or degradation of the device. Differences in thermal expansion coefficients between new and existing materials can cause stress and defects during thermal processing steps. Some (not all) new materials may have different etch and deposition rates, requiring adjustments to processing parameters to achieve desired results. In addition, patterning some (not all) new materials may require modifications to photoresists, exposure tools, and etching processes. Also, existing fabrication equipment may not be compatible with new materials, requiring modifications or new tools. Optimizing the fabrication process for some (not all) new materials can be time-consuming and costly, as it involves numerous iterations and experiments. Modifying or acquiring new equipment can be a significant investment.

Therefore, there is a need to reduce the resistance of BEOL metal wires without changing materials and compatible with current processes, such as the barrier free contact (BFC) process. BFC is a critical process in semiconductor manufacturing that aims to reduce the contact resistance between metal interconnects and semiconductor devices. In traditional contact formation, a barrier layer (typically a metal silicide) is formed between the metal interconnect and the semiconductor. This barrier layer, while preventing unwanted reactions, also introduces additional resistance. BFC eliminates the need for a barrier layer, directly connecting the metal interconnect to the semiconductor. This direct contact reduces contact resistance significantly, leading to improved device performance. Integrating BFC into existing manufacturing processes requires careful optimization to avoid introducing defects or compromising device yield.

In accordance with some aspects of the disclosure, a semiconductor structure is provided. The semiconductor structure includes a substrate; a dielectric layer above the substrate; a low-k dielectric layer disposed on the dielectric layer; a metal plug disposed in the dielectric layer and characterized by a nonplanar top surface of the metal plug, the nonplanar top surface of the metal plug defining a recess; and a metal rivet structure. The metal rivet structure includes a shaft portion penetrating the low-k dielectric layer and characterized by a bottom surface of the shaft portion; and a head portion disposed in the dielectric layer and characterized by a top surface of the head portion and a nonplanar bottom surface of the head portion. The top surface of the head portion is coplanar with the bottom surface of the shaft portion, and the nonplanar bottom surface of the head portion mates with the nonplanar top surface of the metal plug.

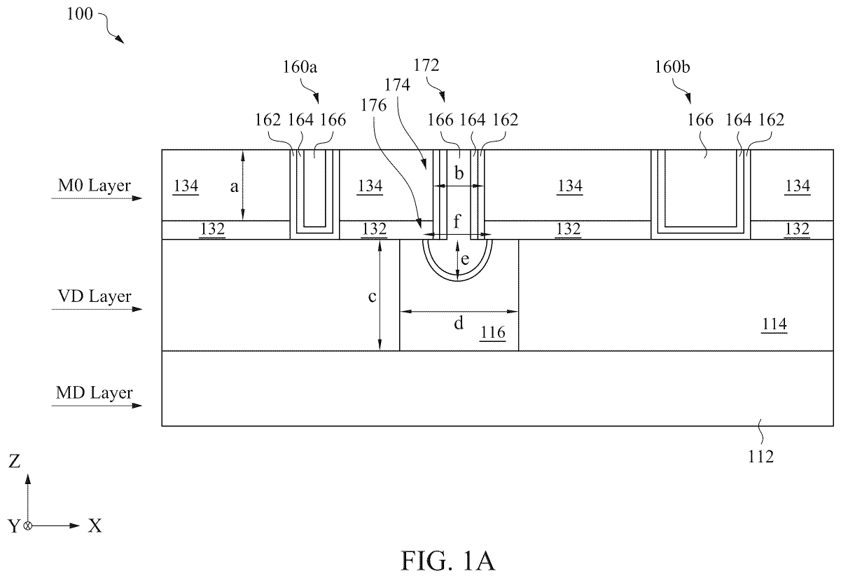

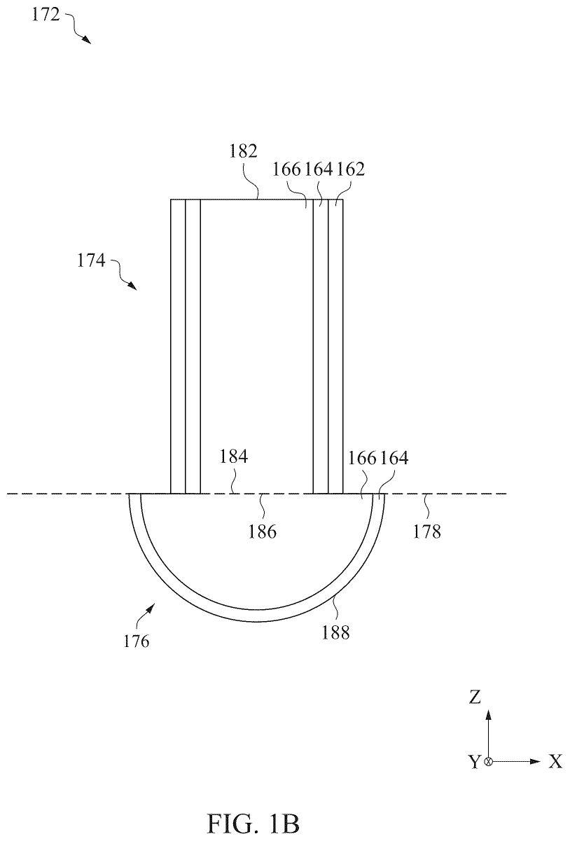

As will be explained in greater detail below, the increase surface area of the interface between the metal rivet structure and the metal plug can lower the contact resistance. Also, since copper has a lower resistivity than the resistivity of tungsten, replacing a portion of the metal plug with the head portion comprising copper can further lower the contact resistance. Details of these features will be discussed below with reference to FIG. 1A-3D.

### Example Semiconductor Structures

FIG. 1A is a cross-sectional diagram illustrating an example semiconductor structure 100 in accordance with some embodiments. FIG. 1B is a diagram illustrating a close-up view of a portion of the semiconductor structure of FIG. 1A in accordance with some embodiments. It should be understood that FIGS. 1A and 1B not drawn to scale.

In the example shown in FIG. 1A, the semiconductor structure 100 is located in the VD layer and the M0 layer above the VD layer. As explained above, the VD layer is below the M0 layer and above the MD layer and provides interconnect between the MD layer and the M0 layer. As such, the metal tracks in the MD layer, which are electrically connected to, for example, sources and drains of semiconductor devices fabricated in the substrate (not shown) below the MD layer, can be electrically connected to metal wires in the M0 layer, which is the first metal layer in a multi-layer interconnect (MLI) structure fabricated using BEOL processes at the backend of a semiconductor chip. It should be understood that the techniques disclosed herein are generally applicable to various types of semiconductor devices, such as Gate-All-Around Field-Effect Transistors (GAAFETs) and Complementary Field-Effect Transistors (CFETs), and the corresponding M0 layer, VD layer, and MD layer.

The semiconductor structure 100 includes, among other components, a metal track 112 in the MD layer, a dielectric layer 114 in the VD layer, a metal plug 116 in the VD layer, an etch stop layer 132 between the VD layer and the M0 layer, a second dielectric layer (e.g., a low-k dielectric layer) 134, and a metal contact structure (may also be referred to as a “metal rivet structure”) 172.

Unlike conventional metal tracks in the M0 layer, which are in contact with metal plugs in the VD layer at the interface 178 (shown in FIG. 1B) between the M0 layer and the VD layer, the metal rivet structure 172 and the metal plug 116 define a nonplanar interface 188 (shown in FIG. 1B). Specifically, the metal rivet structure 172 includes a shaft portion 174 and a head portion 176. The shaft portion is located in the M0 layer and the etch stop layer 132, whereas the head portion 176 is in the VD layer. In other words, unlike conventional metal tracks in the M0 layer, the head portion 176 of the metal rivet structure 172 penetrates into the VD layer and, specifically, the metal plug 116. Also, the metal plug 116 has a nonplanar top surface that defines a recess, and the recess accommodates the head portion 176. As a result, the area of the interface 188, as shown in FIG. 1B, between the metal rivet structure 172 and the metal plug 116 increases. As explained above, the resistivity includes the contribution of surface scattering, which decreases as the surface area increases. As such, the increase surface area of the interface 188 between the metal rivet structure 172 and the metal plug 116 can lower the contact resistance.

In one embodiment, the metal plug 116 comprises tungsten, and the metal rivet structure 172 comprises copper 166. Since copper has a lower resistivity (about 1.68×10⁻⁸ (Ω·m) at 20° C.) than the resistivity (about 5.6×10⁻⁸ (Ω·m) at 20° C.) of tungsten, replacing a portion (the portion in the recess that accommodates the head portion 176) of the metal plug 116 with the head portion 176 comprising copper can further lower the contact resistance. The more replacement of tungsten with copper, the more contact resistance reduction.

As shown in FIG. 1B, the shaft portion 174 is characterized by a top surface 182, a bottom surface 184, and a sidewall extending vertically (i.e., in the Z-direction shown in FIG. 1B) circumferentially between the top surface 182 and the bottom surface 184. The shaft portion 174 includes a barrier layer 162, a liner layer 164, and a metal fill layer 166. In other words, the shaft portion 174 has a multi-layer structure.

The head portion 176 is characterized by a top surface 186. The top surface 186 of the head portion 176 and the bottom surface 184 of the shaft portion 174 interface with each other at the interface 178. The top surface 186 is planar. The area of the top surface 186 is equal to or larger than the area of the bottom surface 184. In other words, the area of the top surface 186 is at least as large as the area of the bottom surface 184. As will be discussed below, this is the result of the etching process during fabrication. The bottom surface 188 of the head portion 176 is a curved surface. The bottom surface 188 of the head portion 176 mates with the top surface of the top surface of the metal plug 116.

The top surface 186 and the bottom surface 188 collectively enclose the head portion 176. The top surface 186 is the interface between the head portion 176 and the shaft portion 174. The top surface 186 and the bottom surface 184 are coplanar. In one example, the head portion 116 is a hemispheroid (i.e., half of a spheroid). In another example, the head portion 116 is a hemisphere. Unlike the shaft portion 174, the head portion 176 includes the liner layer 164 and the metal fill layer 166, but without the barrier layer 162. As will be discussed below, this feature (i.e., without the barrier layer 162) makes the fabrication process of the metal rivet structure 172 compatible with the barrier free contact (BFC) process.

The liner layer 164 promotes strong adhesion between the underlying dielectric layer (often silicon dioxide) and the subsequent metal layers. The liner layer 164 prevents the diffusion of silicon atoms from the substrate into the metal layers, which can degrade electrical performance. During the etching process, the liner layer may act as an etch stop, ensuring precise control over the metal line dimensions. In one example, the liner layer 164 comprises ruthenium (Ru) and cobalt (Co). In another example, the liner layer 164 comprises Co. It should be understood that the liner layer 164 may employ other materials as needed in other embodiments. In one example, the thickness of the liner layer 164 is between 0.5 nm and 2 nm. One of ordinary skill in the art would recognize many variations, modifications, and alternatives.

The barrier layer 162 is essential for preventing the diffusion of copper atoms into the underlying silicon or dielectric layers. Copper, while an excellent conductor, can migrate and cause reliability issues if not properly contained. In one example, the barrier layer 162 comprises tantalum (Ta). In another example, the barrier layer 162 comprises tantalum nitride (TaN). In yet another example, the barrier layer 162 comprises a combination of TaN and Ru (i.e., TaNRu), which can be fabricated using sequential deposition of TaN and Ru or co-sputtering of TaN and Ru. The combined use of TaN and Ru leads to more reliable and durable interconnects, essential for the long-term performance of semiconductor devices. It should be understood that the barrier layer 162 may employ other materials as needed in other embodiments. In one example, the thickness of the barrier layer 162 is between 0.5 nm and 2 nm. One of ordinary skill in the art would recognize many variations, modifications, and alternatives.

The metal fill layer 166 is the primary conductor in the shaft portion 174 of the metal rivet structure 172. By combining these three layers, the multi-layer structure of the shaft portion 174 can offer several benefits. The barrier layer 162 prevents copper diffusion, while the liner layer 164 ensures good adhesion and may act as an etch stop. The high conductivity of copper enables faster signal transmission and reduced power dissipation. The multi-layer structure allows for the fabrication of smaller and more complex integrated circuits.

It should be noted that other metal tracks 160a and 160b are also disposed in the low-k dielectric layer 134, and each of them has a multi-layer structure. Unlike the shaft portion 174, each of the metal tracks 160a and 160b is characterized by a bottom portion of the liner layer 164 and a bottom portion of the barrier layer 162. The metal tracks 160a and 160b in the M0 layer may extend in the Y-direction or the X-direction shown in FIG. 1A to provide appropriate routing as needed. It should be understood that more than two metal tracks may be disposed in the M0 layer as needed. Likewise, more than one metal rivet structure like the metal rivet structure 172 shown in FIG. 1A may be employed as needed. One of ordinary skill in the art would recognize many variations, modifications, and alternatives.

The etch stop layer 132 is operable to protect underlying layers during etching processes, ensuring precise control over the etching depth and pattern formation. The etch stop layer 132 exhibits high etch resistance compared to the materials being protected, good adhesion to the underlying layer, and ability to be selectively removed after the etching process is complete. In one example, the etch stop layer 132 comprises aluminum oxide (AlOₓ). In another example, the etch stop layer 132 comprises aluminum nitride (AlN). In yet another example, the etch stop layer 132 comprises silicon carbonitride (SiCN). In still another example, the etch stop layer 132 comprises silicon oxycarbide (SiOC). In one example, the etch stop layer 132 comprises silicon oxycarbonitride (SiOCN). It should be understood that the etch stop layer 132 may employ other materials as needed in other embodiments. In one example, the thickness of the etch stop player 132 is between 0.5 nm and 10 nm. One of ordinary skill in the art would recognize many variations, modifications, and alternatives.

The low-k dielectric layer 134 serves as an interlayer dielectric (ILD), which electrically isolates different layers of metal interconnects, preventing short circuits and ensuring proper signal propagation. The low dielectric constant reduces capacitive coupling. The low-k dielectric layer 134 may comprise SiON, porous SiO₂, organic polymers, and the like, although other suitable materials may be employed as well. The thickness or height (denoted as “a” in FIG. 1A) of the low-k dielectric layer 134 is between 15 nm and 25 nm. One of ordinary skill in the art would recognize many variations, modifications, and alternatives.

In the example shown in FIG. 1A, the width (denoted as “b” in FIG. 1A) of the shaft portion 174 in the X-direction is between 6 nm and 12 nm, the thickness or height (denoted as “c” in FIG. 1A) of the metal plug 116 in the Z-direction is between 10 nm and 20 nm, the width (denoted as “d” in FIG. 1A) of the metal plug 116 in the X-direction is between 7 nm and 15 nm. In addition, the width (denoted as “f” in FIG. 1A) of the head portion 176 in the X-direction, at the interface 178 shown in FIG. 1B, is equal to or greater than b but smaller than (d−1) nm. In other words, the difference between d and f is larger than 1 nm. Moreover, the depth or height (denoted as “e” in FIG. 1A) of the head portion 176 in the Z-direction is equal to or greater than 1 nm but smaller than c. In other words, the head portion 176 does not reach the bottom surface of the metal plug 116. It should be understood that these geometries (e.g., a, b, c, d, e, as shown in FIG. 1A) are exemplary rather than limiting, and other suitable geometries may be employed.

### Example Fabrication Process Flows

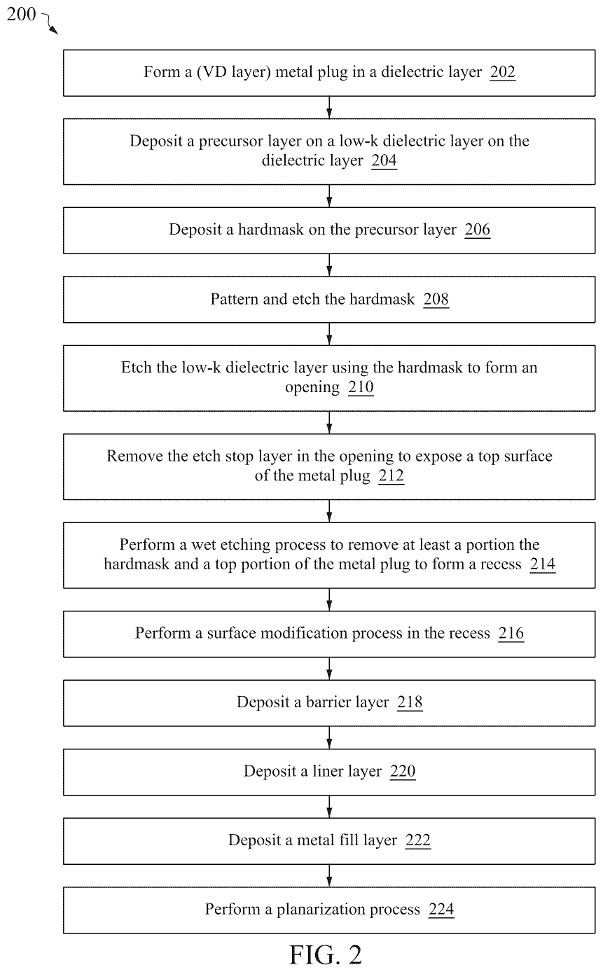

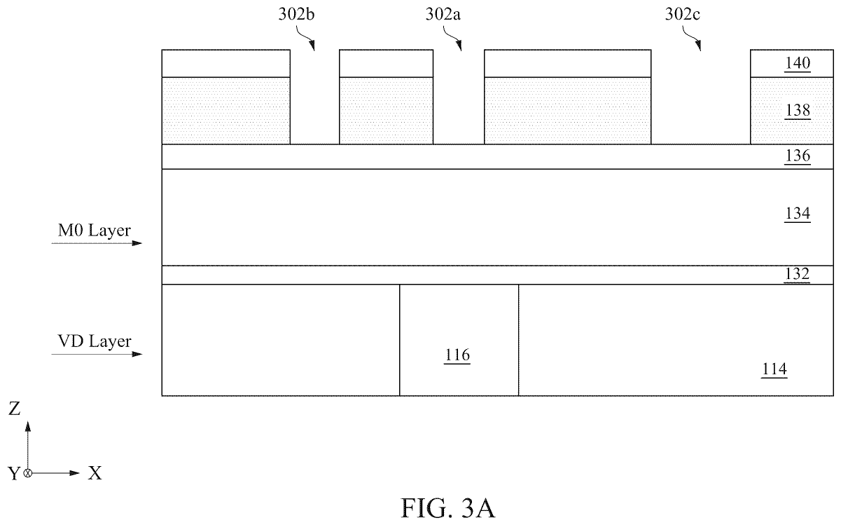

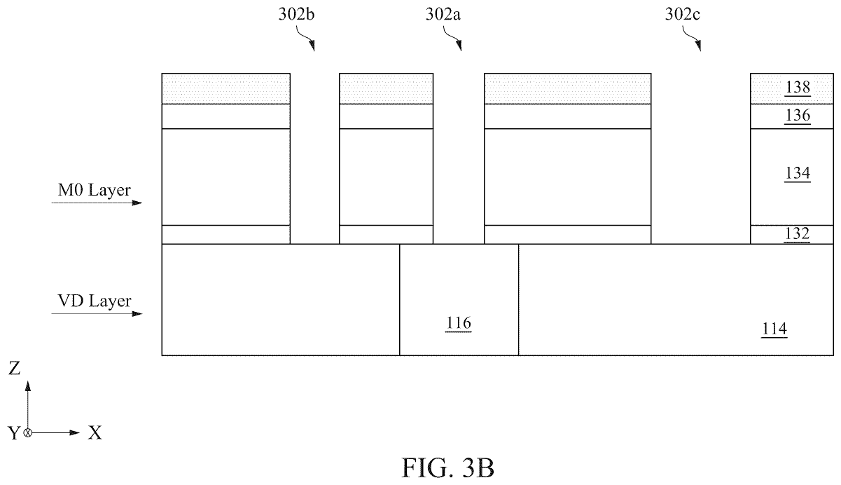

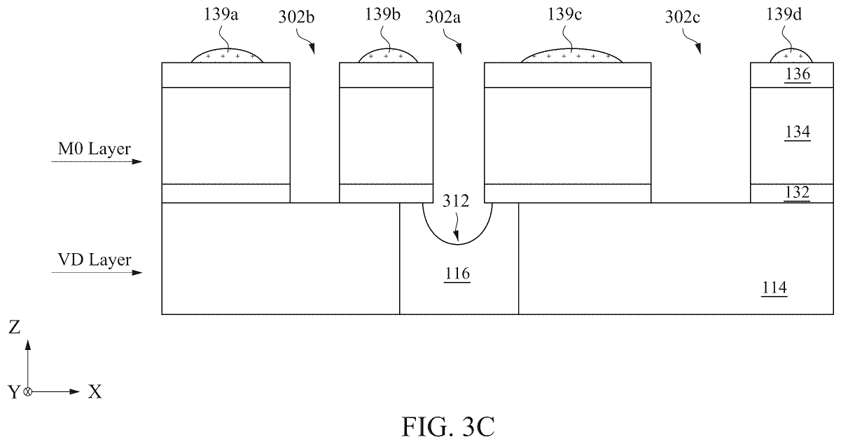

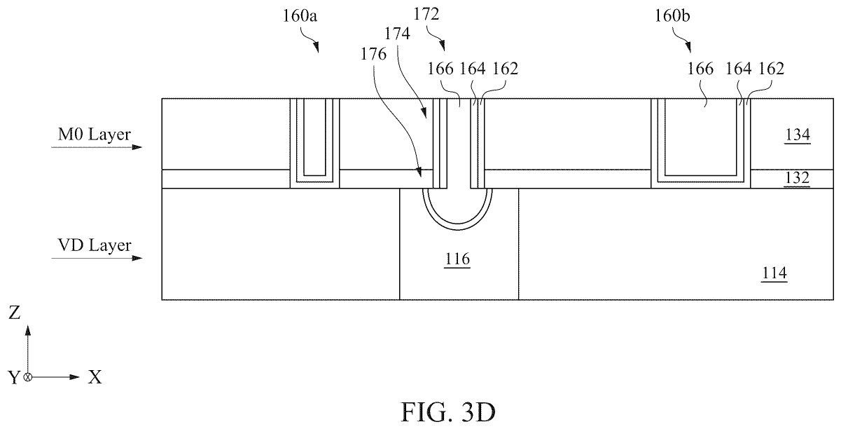

FIG. 2 is a flowchart diagram illustrating an example method 200 in accordance with some embodiments. FIGS. 3A-3D are cross-sectional diagrams illustrating the cross-sections of the structures in various fabrication stages in accordance with some embodiments. In the example shown in FIG. 2, the method 200 includes operations 202, 204, 206, 208, 210, 212, 214, 216, 218, 220, 222, and 224. Additional operations may be performed. Also, it should be understood that the sequence of the various operations discussed above with reference to FIG. 2 is provided for illustrative purposes, and as such, other embodiments may utilize different sequences. These various sequences of operations are to be included within the scope of embodiments.

At operation 202, a (VD layer) metal plug is formed in a low-k dielectric layer. As shown in FIG. 3A, the (VD layer) metal plug 116 is formed in the dielectric layer 114. The dielectric layer and the metal plug 116 are located in the VD layer, which is above the MD layer shown in FIG. 1A. As mentioned above, in one example, the metal plug 116 comprises tungsten. The top surface of the metal plug 116 is a planar surface at this juncture.

At operation 204, a precursor layer is deposited on the low-k dielectric layer. In the example shown in FIG. 3A, the low-k dielectric layer 134 is on the etch stop layer 132, which is on the dielectric layer 114. The precursor layer 136 is on the low-k dielectric layer 134. The precursor layer 136 is operable to facilitate the deposition of the hardmask in the subsequent operation 206 discussed below. In one example, the precursor layer 136 comprises tetraethyl orthosilicate (TEOS). TEOS-based CVD processes produce SiO₂ films with excellent dielectric properties, high thermal stability, and good step coverage. TEOS can be used in various deposition techniques, including atmospheric pressure CVD (APCVD) and low-pressure CVD (LPCVD), allowing for precise control over film thickness and properties.

At operation 206, a hardmask is deposited on the precursor layer. In the example shown in FIG. 3A, the hardmask 138 is deposited on the precursor layer 136. The hardmask 138 is a thin, durable layer of material used in semiconductor manufacturing to protect underlying layers during etching processes. The hardmask 138 is more resistant to etching than photoresists, preventing it from being eroded during the etching process. It also provides excellent etch selectivity, ensuring that only the desired material is removed. In one example, the hardmask 138 comprises carbon-doped tungsten (W—C). In one implementation, the carbon-doped tungsten is formed by introducing carbon-containing gases, such as methane or acetylene, into a CVD reactor along with tungsten precursors. Carbon-doped tungsten exhibits high resistance to various etchants, including those used for etching silicon dioxide and silicon nitride. In one example, the hardmask 138 comprises SiO₂. In another example, the hardmask 138 comprises silicon nitride (Si₃N₄).

At operation 208, the hardmask is patterned and etched. In the example shown in FIG. 3A, the hardmask 138 is patterned and etched using a photoresist layer 140, and openings 302a, 302b, and 302c are formed accordingly. The opening 302a is above the metal plug 116 and corresponds to the shaft portion 174 of the metal rivet structure 172 shown in FIG. 1A. The openings 302b and 302c correspond to other M0 metal tracks 160a and 160b shown in FIG. 1A.

At operation 210, the low-k dielectric layer is etched, using the hardmask, to form an opening. In the example shown in FIG. 3B, the low-k dielectric layer 134 is etched at locations where it is exposed by the hardmask 138.

At operation 212, the etch stop layer in the opening is removed to expose a top surface of the metal plug. In the example shown in FIG. 3B, the etch stop layer 132 is etched at locations where it is exposed by the hardmask 138. As such, the openings 302a, 302b, and 302c extend to the top surface of the dielectric layer 114 and the metal plug 116.

At operation 214, a wet etching process is performed to remove at least a portion the hardmask and a top portion of the metal plug to form a recess. In the example shown in FIG. 3C, after the wet etching process, a portion of the hardmask 138 is etched, and islands 139a, 139b, 139c, and 139d (collectively, 139) of the original hardmask 138 are formed. These islands 139 reduce the overhang during the deposition of the barrier layer, the liner layer, and the metal fill layer in subsequent operations, thereby mitigating the risk of forming voids in the openings 302 when the aspect ratio is high. In addition, the reduced overhang can enable a relatively thin barrier layer and a relatively thin liner layer, thereby reducing the resistance. In some embodiments, the hardmask 138 may be completely removed. In other words, there are no islands 139 in these embodiments.

On the other hand, since the hardmask 138 comprises carbon-doped tungsten and the metal plug 116 comprises tungsten in some embodiments, the metal plug 116 is also etched simultaneously. Thus, the wet etching process serves two functions (i.e., creating the islands 139 and creating the recess 312) simultaneously. As a result of the wet etching process, a recess 312 is formed. The isotropic nature of the wet etching process contributes to the profile or shape of the recess 312. The recess 312 corresponds to the head portion 176 shown in FIG. 1A and formed in subsequent operations.

In some examples, the etchant for the wet etching process is a potassium ferricyanide-based etchant (e.g., a mildly alkaline solution). In other examples, the etchant for the wet etching process is an acid-based etchant (e.g., nitric acid, hydrofluoric acid, etc.). It should be understood that these examples are not intended to be limiting, and other suitable etchants may be employed as needed. One of ordinary skill in the art would recognize many variations, modifications, and alternatives.

At operation 216, a surface modification process is performed in the recess. In the example shown in FIG. 3C, the surface of the recess 312 is modified using a surface modification process. After the surface modification process, the property of the surface of the metal plug 116 in the recess 312 is modified so that it prevents barrier layer from being deposited on it in the subsequent operation.

In one implementation, the surface of the metal plug 116 in the recess 312 is modified by applying (e.g., by spin coating) inhibitor molecules. In one example, the inhibitor molecules comprise a self-assembled monolayer (SAM). SAMs are molecules that can self-assemble on a surface to form a protective layer. By selectively applying SAMs to specific regions, it's possible to prevent the deposition of the barrier layer in those areas. The SAM may include a head group connected to the surface of the metal plug 116 in the recess 312, a terminal group, and a chain group connecting the head group and the terminal group. The head group exhibits a hydrophilic interfacial property that results in the adhesion to the surface of the metal plug 116 in the recess 312. The terminal group makes it less reactive to the precursors used in the deposition of the barrier layer.

In other examples, the inhibitor molecules comprise small molecule inhibitors, which can block the active sites on the surface, thereby preventing the adsorption of the barrier layer precursor. That is, the SAM prevents or blocks the deposition of the barrier layer. One of ordinary skill in the art would recognize many variations, modifications, and alternatives.

At operation 218, a barrier layer is deposited. In the example shown in FIG. 3D, the barrier layer 162 is conformally deposited in the openings 302a, 302b, and 302c shown in FIG. 3C. Because of the surface modification process (e.g., by using SAM) performed at operation 216, the barrier layer 162 is not formed on the surface of the metal plug 116 in the recess 312. In contrast, the barrier layer 162 is deposited at the bottom surface of the openings 302a and 302b shown in FIG. 3C. As such, barrier free contacts are achieved at the desired locations by selectively applying the inhibitor molecules (e.g., SAMs). In some implementations, the barrier layer 162 is formed using, for example, Physical Vapor Deposition (PVD), Chemical Vapor Deposition (CVD), Atomic Layer Deposition (ALD), and other suitable processing techniques.

One of ordinary skill in the art would recognize many variations, modifications, and alternatives.

In one example, the barrier layer 162 comprises tantalum (Ta). In another example, the barrier layer 162 comprises tantalum nitride (TaN). In yet another example, the barrier layer 162 comprises a combination of TaN and Ru (i.e., TaNRu), which can be fabricated using sequential deposition of TaN and Ru or co-sputtering of TaN and Ru. It should be understood that the barrier layer 162 may employ other materials as needed in other embodiments. In one example, the thickness of the barrier layer 162 is between 0.5 nm and 2 nm.

In some embodiments, a removal process is performed to remove the inhibitor molecules (e.g., SAM) from the top surface of the metal plug 116 in the recess 312. In some implementations, the removal process includes exposing the structure of to a removal plasma that is configured to remove the inhibitor molecules. Other suitable techniques may be employed as well in other implementations. One of ordinary skill in the art would recognize many variations, modifications, and alternatives. The process is compatible with a regular barrier free contact (BFC) process.

At operation 220, a liner layer is deposited. In the example shown in FIG. 3D, the liner layer 164 is conformally deposited in the openings 302a, 302b, 302c as well as the recess 312 shown in FIG. 3C. Since there is no barrier layer 162 deposited on the top surface of the metal plug 116 in the recess 312, the liner layer 164 is deposited on the top surface of the metal plug 116. In some implementations, the barrier layer 162 is formed using, for example, Physical Vapor Deposition (PVD), Chemical Vapor Deposition (CVD), Atomic Layer Deposition (ALD), and other suitable processing techniques. One of ordinary skill in the art would recognize many variations, modifications, and alternatives.

In one example, the liner layer 164 comprises ruthenium (Ru) and cobalt (Co). In another example, the liner layer 164 comprises Co. It should be understood that the liner layer 164 may employ other materials as needed in other embodiments. In one example, the thickness of the liner layer 164 is between 0.5 nm and 2 nm.

At operation 222, a metal fill layer is deposited. In the example shown in FIG. 3D, the metal fill layer 166 is conformally deposited in the openings 302a, 302b, 302c as well as the recess 312 shown in FIG. 3C. In some implementations, the metal fill layer 166 is formed using, for example, electroplating, Physical Vapor Deposition (PVD) including sputtering or evaporation, and other suitable processing techniques. One of ordinary skill in the art would recognize many variations, modifications, and alternatives.

As explained above, the islands 139 shown in FIG. 3C reduce the overhang during the deposition of the barrier layer 162, the liner layer 164, and the metal fill layer 166, thereby mitigating the risk of forming voids in the openings 302a, 302b, and 302c when the aspect ratio is high. In addition, the reduced overhang can enable a relatively thin barrier layer 162 and a relatively thin liner layer 164, thereby reducing the resistance.

At operation 224, a planarization process is performed. In the example shown in FIG. 3D, after the planarization process, the excessive portions of the barrier layer 162, the liner layer 164, and the metal fill layer 166 outside the openings 302a, 302b, and 302c are removed. The top surfaces of the low-k dielectric layer 134, the the barrier layer 162, the liner layer 164, and the metal fill layer 166 become coplanar to enable subsequent processing operations. In one implementation, the planarization process is a Chemical Mechanical Planarization (CMP) process, which involves the combined action of chemical and mechanical forces to remove material selectively. A chemical slurry is applied to the wafer surface. This slurry contains chemical agents that react with the wafer material, weakening its bonds and making it more susceptible to mechanical removal. On the other hand, a rotating pad, often made of polyurethane or other specialized materials, is pressed against the wafer surface. The abrasive particles in the slurry, along with the mechanical force, remove material from the high points on the wafer, effectively smoothing the surface. One of ordinary skill in the art would recognize many variations, modifications, and alternatives.

### General Applicability of the Techniques

Although the techniques disclosed herein are described in the context of the VD layer and the M0 layer, it should be understood these techniques are generally applicable to other BEOL processing applications. For example, the metal plug can be located in a M1 layer (i.e., the metal layer above and immediately after the M0 layer), and the shaft portion of the metal rivet structure can be located in the M2 layer (i.e., the metal layer above and immediately after the M0 layer). As another example, the metal plug can be located in the M0 layer, and the shaft portion of the metal rivet structure can be located in the M1 layer. For instance, the metal plug can be located in a M3 layer, and the shaft portion of the metal rivet structure can be located in a M4 layer above and immediately after the M3 layer. In short, the techniques may be applied to the interface between metal wires located in two neighboring layers in the multi-layer structure (MLI) at the back end of a semiconductor chip.

### Summary

In accordance with some aspects of the disclosure, a semiconductor structure is provided. The semiconductor structure comprises: a substrate; a dielectric layer above the substrate; a second dielectric layer disposed on the dielectric layer; a metal plug disposed in the dielectric layer and comprising a nonplanar top surface of the metal plug, the nonplanar top surface of the metal plug defining a recess; and a metal rivet structure. The metal rivet structure comprises: a shaft portion penetrating the second dielectric layer and comprising a bottom surface of the shaft portion; and a head portion located in the dielectric layer and comprising a top surface of the head portion and a nonplanar bottom surface of the head portion, wherein the top surface of the head portion is coplanar with the bottom surface of the shaft portion, and the nonplanar bottom surface of the head portion mates with the nonplanar top surface of the metal plug.

In accordance with some aspects of the disclosure, a metal rivet structure disposed at a back end of a semiconductor chip is provided. The metal rivet structure comprises: a shaft portion penetrating a second dielectric layer and comprising a bottom surface of the shaft portion; and a head portion located in a dielectric layer below the second dielectric layer and comprising a top surface of the head portion and a nonplanar bottom surface of the head portion, wherein the top surface of the head portion is coplanar with the bottom surface of the shaft portion, and the nonplanar bottom surface of the head portion is operable to mate with a nonplanar top surface of a metal plug.

In accordance with some aspects of the disclosure, a method is provided. The method comprises: forming a metal plug in a dielectric layer; depositing a low-k dielectric layer on the dielectric layer; depositing a hardmask on the low-k dielectric layer; patterning and etching the hardmask; etching the low-k dielectric layer using the patterned hardmask to form an opening to expose a top surface of the metal plug; performing a wet etching process to remove: at least a portion of the patterned hardmask; and a top portion of the metal plug to form a recess; depositing a barrier layer; depositing a liner layer; and depositing a metal fill layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a substrate;
a dielectric layer above the substrate;
a second dielectric layer disposed on the dielectric layer;
a metal plug disposed in the dielectric layer and comprising a nonplanar top surface of the metal plug, the nonplanar top surface of the metal plug defining a recess; and
a metal rivet structure comprising:
a shaft portion penetrating the second dielectric layer and comprising a bottom surface of the shaft portion; and
a head portion located in the dielectric layer and comprising a top surface of the head portion and a nonplanar bottom surface of the head portion, wherein the top surface of the head portion is coplanar with the bottom surface of the shaft portion, and the nonplanar bottom surface of the head portion mates with the nonplanar top surface of the metal plug.

2. The semiconductor structure of claim 1, wherein the head portion comprises a liner layer in contact with the metal plug and a metal fill layer on the liner layer.

3. The semiconductor structure of claim 2, wherein no barrier layer is disposed between the liner layer of the head portion and the metal plug.

4. The semiconductor structure of claim 1, wherein the shaft portion comprises a barrier layer, a liner layer, and a metal fill layer, the barrier layer laterally surrounding the liner layer, the liner layer laterally surrounding the metal fill layer.

5. The semiconductor structure of claim 1, wherein a first area of the top surface of the head portion is equal to or greater than a second area of the bottom surface of the shaft portion.

6. The semiconductor structure of claim 1, wherein a thickness of the second dielectric layer is between 15 nm and 25 nm.

7. The semiconductor structure of claim 1, wherein a width of the shaft portion is between 6 nm and 12 nm.

8. The semiconductor structure of claim 1, wherein a height of the head portion is greater than 1 nm.

9. The semiconductor structure of claim 1, wherein a height of the metal plug is between 10 nm and 20 nm.

10. The semiconductor structure of claim 1, wherein a width of the metal plug is between 7 nm and 15 nm.

11. The semiconductor structure of claim 1, wherein the head portion is a hemispheroid.

12. The semiconductor structure of claim 1, wherein the head portion is a hemisphere.

13. The semiconductor structure of claim 1, wherein the metal plug comprises tungsten, and a metal fill layer of the metal rivet structure comprises copper.

14. The semiconductor structure of claim 1, wherein the dielectric layer is located in a first contact layer, and the second dielectric layer is located in a first metal layer, the first contact layer is between the first metal layer and a device connection layer.

15. A metal rivet structure disposed at a back end of a semiconductor chip, the metal rivet structure comprising:
a shaft portion penetrating a second dielectric layer and comprising a bottom surface of the shaft portion; and
a head portion located in a dielectric layer below the second dielectric layer and comprising a top surface of the head portion and a nonplanar bottom surface of the head portion, wherein the top surface of the head portion is coplanar with the bottom surface of the shaft portion, and the nonplanar bottom surface of the head portion is operable to mate with a nonplanar top surface of a metal plug.

16. The metal rivet structure of claim 15, wherein the head portion comprises a liner layer in contact with the metal plug and a metal fill layer on the liner layer.

17. The metal rivet structure of claim 16, wherein no barrier layer is disposed between the liner layer of the head portion and the metal plug.

18. The metal rivet structure of claim 15, wherein the head portion is a hemispheroid.

19. A method comprising:
forming a metal plug in a dielectric layer;
depositing a low-k dielectric layer on the dielectric layer;
depositing a hardmask on the low-k dielectric layer;
patterning and etching the hardmask;
etching the low-k dielectric layer using the patterned hardmask to form an opening to expose a top surface of the metal plug;
performing a wet etching process to remove:
at least a portion of the patterned hardmask; and
a top portion of the metal plug to form a recess;
depositing a barrier layer;
depositing a liner layer; and
depositing a metal fill layer.

20. The method of claim 19, further comprising:
performing a surface modification process in the recess to prevent the barrier layer from being deposited on the top surface of the metal plug in the recess.
